(19) United States
(12) Patent Application Publication
(10) Pub. No.: US 2026/0096135 A1
(43) Pub. Date: Apr. 2, 2026

(54) Semiconductor structure and manufacturing method thereof

(71) Applicant: UNITED MICROELECTRONICS CORP., Hsin-Chu City (TW)

(72) Inventors: Huang-I Chen, Tainan City (TW); Cheng-Hsin Lee, Tainan City (TW); Cheng-Hua Chou, Tainan City (TW)

(73) Assignee: UNITED MICROELECTRONICS CORP., Hsin-Chu City (TW)

(21) Appl. No.: 18/938,230

(22) Filed: Nov. 5, 2024

(30) Foreign Application Priority Data
Oct. 1, 2024 (TW) 113137571

(51) Int. Cl. H01L 29/78; H01L 21/02; H01L 21/311; H01L 21/3115; H01L 21/762; H01L 29/06; H01L 29/66

(52) U.S. Cl. CPC H10D 30/6215; H10D 30/024; H10D 62/10; H10D 62/126; H10P 14/68; H10P 32/20; H10P 50/283; H10W 10/014; H10W 10/17

(57) ABSTRACT

The invention provides a method for manufacturing a semiconductor structure, which comprises the following steps: providing a substrate with a shallow trench isolation structure and a first active area, wherein a top surface of the shallow trench isolation structure is higher than a top surface of the substrate in the first active area, performing an etching step to remove part of the shallow trench isolation structure so that the top surface of the shallow trench isolation structure is lower than that of the substrate in the first active area, and after the etching step, a doping step is performed on the first active area.

### BACKGROUND OF THE INVENTION

### 1. Field of the Invention

The invention relates to the field of semiconductors, in particular to a method for manufacturing an improved planar transistor, which can effectively improve the efficiency of the planar transistor.

### 2. Description of the Prior Art

With the rapid development of science and technology, the requirements of electronic products for efficiency and function are constantly improving, which also drives the semiconductor technology to move forward. In order to accommodate more transistors in the limited chip area, achieve higher computing power and lower power consumption, the design of semiconductor components has gradually shifted from the traditional planar structure to three-dimensional.

Planar Transistor has always been an important component in the semiconductor industry. It has simple structure, relatively easy manufacturing process and high cost-effectiveness, and is widely used in various electronic products. Planar transistors are mainly used in 28 nm and 22 nm processes. However, with the continuous miniaturization of semiconductor processes and the smaller size of transistors, the physical limitations of planar transistors gradually emerge. When the process enters 17 nm, 14 nm or even more advanced nodes, planar transistors face challenges in controlling leakage current and maintaining performance.

At present, fin filed effect transistor (FinFET) came into being. FinFET adopts a three-dimensional structure, the channel of the transistor protrudes from the substrate, and the gate surrounds the three sides of the channel, which realizes better gate control ability, effectively reduces leakage current and improves transistor performance. The appearance of FinFET makes the semiconductor manufacturing process continue to shrink, which lays the foundation for the development of high-performance chips.

Although FinFET plays a key role in advanced manufacturing process, planar transistors have not been completely replaced. Planar transistors have the advantages of simple structure and easy manufacturing process, so they are still widely used in some middle-level devices with low performance requirements. In addition, in some special applications, such as power management chips, the characteristics of planar transistors still have advantages.

### SUMMARY OF THE INVENTION

The invention provides a method for manufacturing a semiconductor structure, which comprises the following steps: providing a substrate with a shallow trench isolation structure and a first active area, wherein a top surface of the shallow trench isolation structure is higher than a top surface of the substrate in the first active area, performing an etching step to remove part of the shallow trench isolation structure so that the top surface of the shallow trench isolation structure is lower than that of the substrate in the first active area, and performing a doping step on the first active area after the etching step.

The invention also provides a semiconductor structure, which comprises a substrate with a first active area, a shallow trench isolation structure located on the substrate and around the first active area, wherein a top surface of the shallow trench isolation structure is lower than a top surface of the substrate of the first active area, and a height difference between the top surface of the shallow trench isolation structure and the top surface of the first active area is defined as H1, where H1 is between 2 nm and 10 nm.

The invention is characterized in that planar transistors are still the main application components in the intermediate-level semiconductor manufacturing processes such as 22 nm and 28 nm. In the manufacturing process of the planar transistor, the surface of the shallow trench isolation structure is slightly lowered by an additional etching process, so that the original planar active area presents a protruding part similar to the fin structure, thereby improving the performance of the transistor. It is noteworthy that the improved planar transistor of the present invention is different from the conventional fin transistor, and the present invention can form a planar transistor with a protruding active area without multiple additional processes. The planar transistor of the present invention is suitable for intermediate semiconductor processes such as 22 nm and 28 nm, and has the advantages of easy process, simple structure, etc. At the same time, because the active area becomes a protruding structure, the transistor has higher performance.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

In order to make the following easier to understand, readers can refer to the drawings and their detailed descriptions at the same time when reading the present invention. Through the specific embodiments in the present specification and referring to the corresponding drawings, the specific embodiments of the present invention will be explained in detail, and the working principle of the specific embodiments of the present invention will be expounded. In addition, for the sake of clarity, the features in the drawings may not be drawn to the actual scale, so the dimensions of some features in some drawings may be deliberately enlarged or reduced.

FIG. 1 to FIG. 5 are schematic cross-sectional views of a semiconductor structure for according to an embodiment of that present invention.

FIG. 6 shows a schematic diagram of a semiconductor structure of the present invention and a schematic diagram of a fin transistor.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

Although the present invention uses the terms first, second, third, etc. to describe elements, components, regions, layers, and/or sections, it should be understood that such elements, components, regions, layers, and/or sections should not be limited by such terms. These terms are only used to distinguish one element, component, region, layer and/or block from another element, component, region, layer and/or block. They do not imply or represent any previous ordinal number of the element, nor do they represent the arrangement order of one element and another element, or the order of manufacturing methods. Therefore, the first element, component, region, layer or block discussed below can also be referred to as the second element, component, region, layer or block without departing from the specific embodiments of the present invention.

The term “about” or “substantially” mentioned in the present invention usually means within 20% of a given value or range, such as within 10%, or within 5%, or within 3%, or within 2%, or within 1%, or within 0.5%. It should be noted that the quantity provided in the specification is approximate, that is, the meaning of “about” or “substantially” can still be implied without specifying “about” or “substantially”.

The terms “coupling” and “electrical connection” mentioned in the present invention include any direct and indirect means of electrical connection. For example, if the first component is described as being coupled to the second component, it means that the first component can be directly electrically connected to the second component, or indirectly electrically connected to the second component through other devices or connecting means.

Although the invention of the present invention is described below by specific embodiments, the inventive principles of the present invention can also be applied to other embodiments. In addition, in order not to obscure the spirit of the present invention, specific details are omitted, and the omitted details are within the knowledge of those with ordinary knowledge in the technical field.

Please refer to FIGS. 1 to 5. FIGS. 1 to 5 illustrate schematic cross-sectional views of a semiconductor structure formed according to an embodiment of the present invention. First, as shown in FIG. 1, a substrate S is provided, for example, but not limited to a silicon substrate. A first active area AA1 and a second active area AA2 are defined on the substrate S, and a shallow trench isolation structure STI is included between the first active area AA1 and the second active area AA2, wherein the shallow trench isolation structure STI consists of a bottom liner 10 and an upper insulating layer 12. In this embodiment, the material of the liner 10 and the material of the insulating layer 12 are, for example, silicon oxide, but the invention is not limited to this. The function of the liner 10 is mainly to prevent ion diffusion and stabilize stress. In other embodiments of the present invention, it is also possible to omit the liner 10 and directly form the insulating layer 12 in the substrate S, which is also within the scope of the present invention.

In this embodiment, an oxide layer 14 and a nitride layer 16 are formed on the surface of the substrate S. After the oxide layer 14 and the nitride layer 16 are formed on the surface of the substrate S, one or more etching steps are performed to form a groove (not shown) in the nitride layer 16, the oxide layer 14 and the substrate S, and then the material layers, such as a silicon nitride material layer and a silicon oxide material layer, which constitute the liner 10 and the insulating layer 12, are filled in the groove. Then, a planarization step (such as chemical mechanical polishing) is used to remove the redundant silicon nitride material layer and silicon oxide material layer, and the remaining material layers are defined as the liner 10 and the insulating layer 12. At this time, as shown in FIG. 1, after the planarization step, the top surface of the nitride layer 16, the top surface of the liner 10 and the top surface of the insulating layer 12 are aligned with each other in the horizontal direction.

Among them, the first active area AA1 and the second active area AA2 defined here, in the subsequent steps, will form transistors in which the gates are located respectively. The first active area AA1 and the second active area AA2 can form different types of transistors by doping different ions, for example, doping P-type ions and N-type ions in the first active area AA1 and the second active area AA2 to form P-type and N-type doped regions respectively, and then forming different types of transistors in the two regions after the gates are respectively formed in the first active area AA1 and the second active area AA2. For example, the first active area AA1 contains a P-type doped region, so that an N-type transistor can be formed, while the second active area AA2 contains an N-type doped region, so that a P-type transistor can be formed. It should be noted that the above-mentioned embodiment is only one example of the present invention, and in other embodiments of the present invention, both sides of the shallow trench isolation structure STI may also contain doped regions of the same type and form transistors of the same type, and this variation is also within the scope of the present invention.

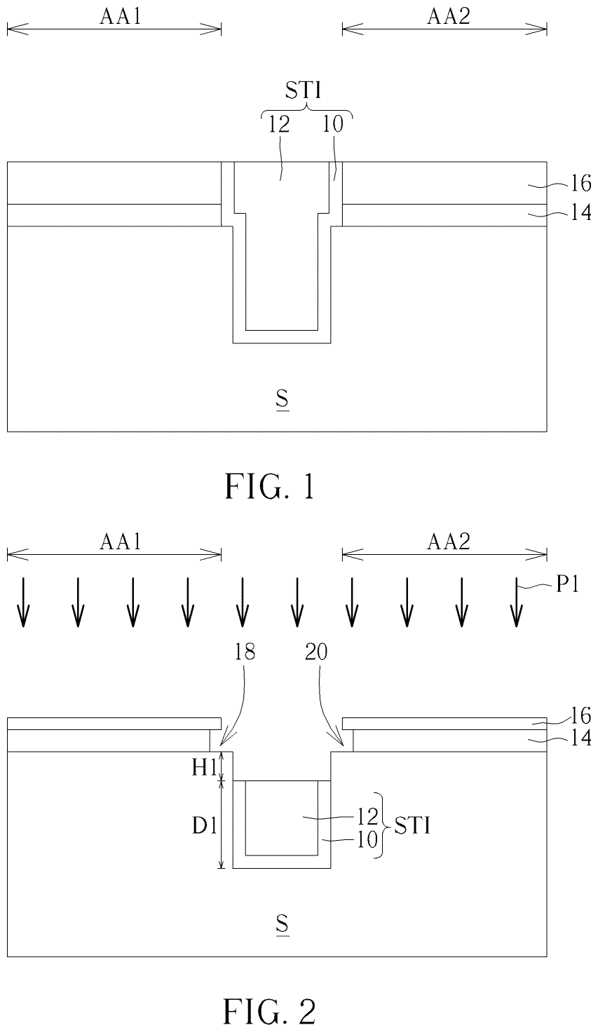

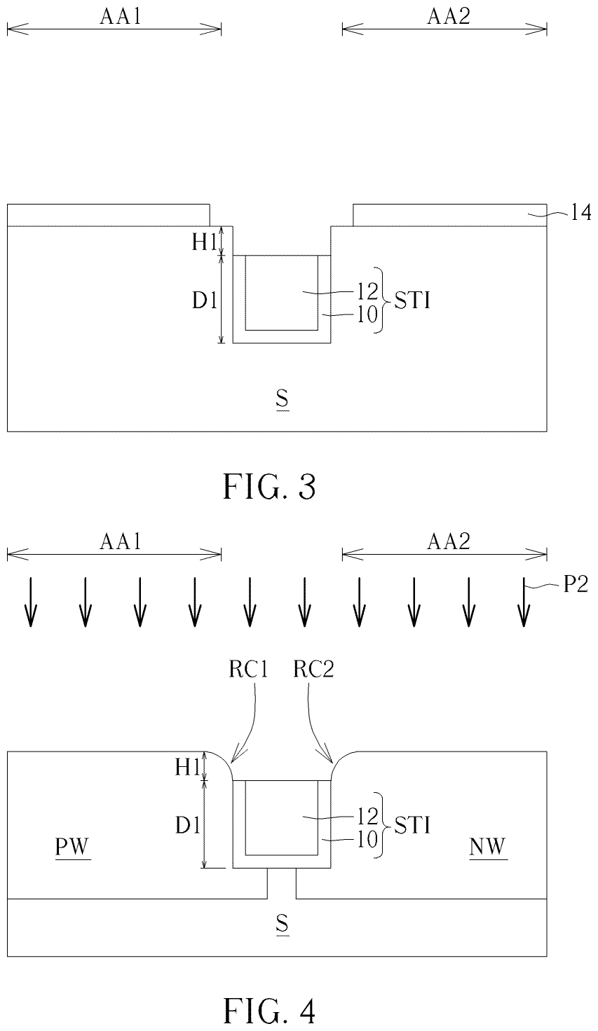

Next, as shown in FIGS. 2 and 3, after the planarization step is completed, a wet etching step is performed. The wet etching step P1 is, for example, a buffered oxide etch (BOE), and the device is immersed in a mixed solution of hydrofluoric acid (HF) and ammonium fluoride (NH₄F). The main function of BOE is to etch the silicon oxide layer. It is worth noting that the wet etching step P1 does not need to use an additional mask, but isotropically etches the silicon oxide layer of the whole semiconductor structure. In the wet etching step P1, the insulating layer 12 and the oxide layer 14 made of silicon oxide will be the main etching targets, so the liner 10, the insulating layer 12 and the oxide layer 14 are removed at a faster rate. In addition, the nitride layer 16 made of silicon nitride may also be partially removed. In addition, because the removal rate of silicon oxide is faster than that of silicon nitride during the wet etching step P1, the oxide layer 14 will be removed more easily, so that the oxide layer 14 produces a notch 18 and a notch 20 between the substrate S and the nitride layer 16.

Then, as shown in FIGS. 3 and 4, the nitride layer 16 and the oxide layer 14 on the surface of the substrate S are removed by one or more etching steps. Next, one or more doping steps P2 are performed in the first active area AA1 and the second active area AA2, so as to form doped regions in the first active area AA1 and the second active area AA2 respectively. The doped regions in the first active area AA1 and the second active area AA2 can be of the same type or different types. Taking this embodiment as an example, for example, boron ions are doped in the first active area AA1 and phosphorus ions or arsenic ions are doped in the second active area AA2 to form a P-type doped region PW in the substrate S of the first active area AA1, and an N-type doped region NW in the substrate of the second active area AA2. Here, the P-doped region PW and the N-doped region NW can be regarded as a first active area and a second active area respectively, and gate structures will be formed on the first active area and the second active area respectively in the following steps to form transistors. As mentioned above, the invention does not limit the types of doped regions formed by the first active area AA1 and the second active area AA2 shown here, that is, it can be adjusted according to actual needs.

In addition, it is worth noting that in the process of FIGS. 2 to 4, the etching parameters or ion doping parameters can be selectively adjusted, so that rounded corners RC1 and RC2 are generated at the interface of P-doped region PW or N-doped region NW and shallow trench isolation structure STI. The rounded corner RC1 and the rounded corner RC2 are helpful to reduce the leakage current of the transistor formed subsequently, so as to achieve the effect of improving the quality of the semiconductor structure. However, the present invention is not limited to forming the rounded corners RC1 and RC2, so in other embodiments of the present invention, the semiconductor structure may not include the rounded corners RC1 and RC2, and this variation is also within the scope of the present invention.

It is also worth noting that after the wet etching step P1 in FIG. 2, the top surface of the shallow trench isolation structure STI will descend and be lower than the top surface of the substrate S, and then the substrate S will be doped in the step shown in FIG. 4. That is, the top surfaces of the P-doped region PW as the first active area AA1 and the N-doped region NW as the second active area AA2 will be higher than the top surface of the shallow trench isolation structure STI. However, in the present invention, the height difference between the top surface of the P-doped region PW or the N-doped region NW and the top surface of the shallow trench isolation structure STI is limited within a certain range. More specifically, the height difference between the top surface of the P-doped region PW or the N-doped region NW and the top surface of the shallow trench isolation structure STI is defined as H1, and the depth of the shallow trench isolation structure STI is defined as D1 (that is, the length from the top surface to the bottom surface of the shallow trench isolation structure STI in the vertical direction when viewed from the cross section). In the present invention, the height H1 is within about 10 nm, and the depth D1 is within about 200 nm. More specifically, the height H1 in this embodiment is only about 4 nanometers. That is, relative to the depth D1 of the shallow trench isolation structure STI, the height H1 of the active area (i.e., the P-doped region PW and the N-doped region NW) protruding from the top surface of the shallow trench isolation structure STI is less. For example, in this embodiment, the ratio of the height H1 to the depth D1 is about 0.05 or less (i.e. 10/200), but the present invention is not limited to this.

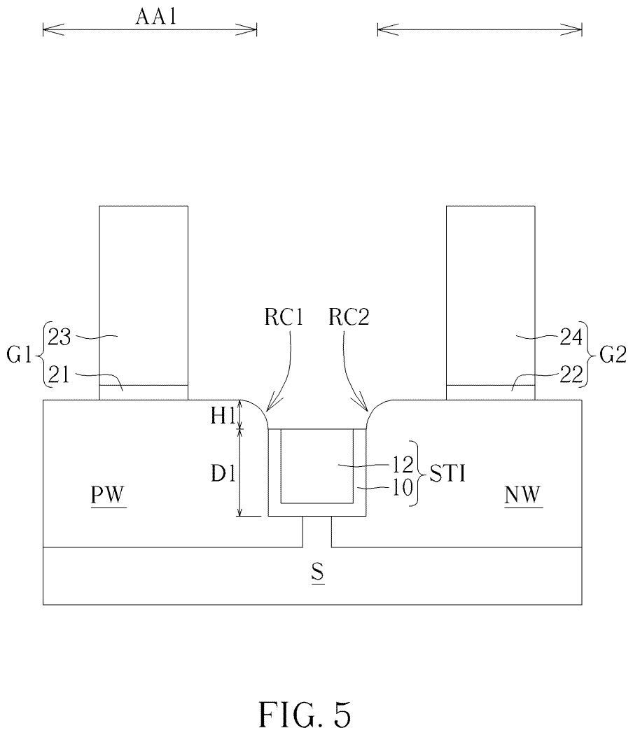

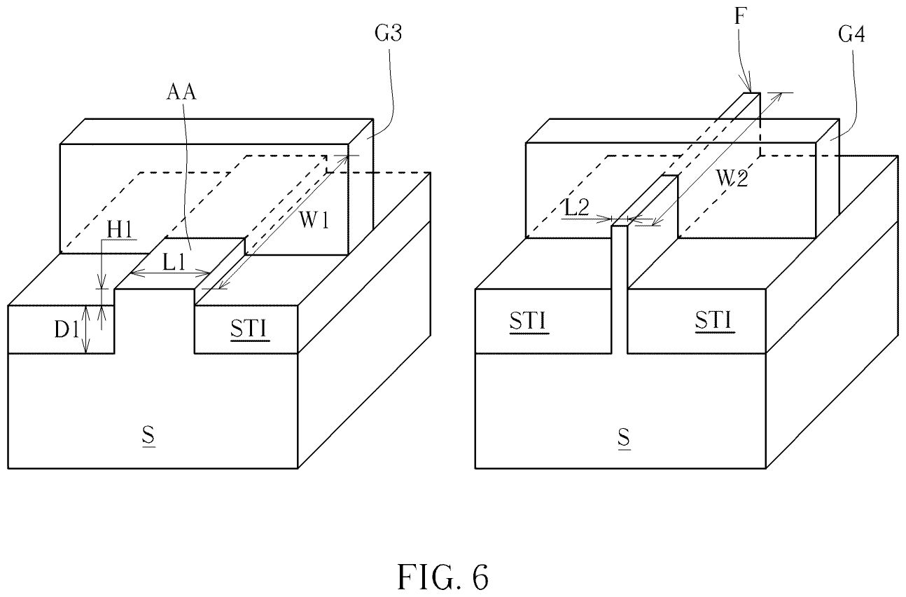

Next, as shown in FIG. 5, a gate structure G1 and a gate structure G2 are formed on the surfaces of the P-doped region PW and the N-doped region NW, respectively. After the gate structure G1 and the gate structure G2 are formed, two different types of transistors are respectively formed in the first active area AA1 and the second active area AA2. The gate structure G1 includes a gate dielectric layer 21 and a gate conductive layer 23, and the gate structure G2 includes a gate dielectric layer 22 and a gate conductive layer 24. The gate dielectric layer 21 and the gate dielectric layer 22 described here may include a stacked structure of silicon oxide, a high dielectric constant layer, a work function metal layer and other material layers. The gate conductive layer 23 and the gate conductive layer 24 may comprise polysilicon or conductive metal layer. Since the steps of forming the gate structure and the material characteristics of the gate structure belong to the prior art in this field, they are not detailed here. In addition, in the actual manufacturing process, the periphery of the first active area AA1 (the P-doped region PW) or the second active area AA2 (the N-doped region NW) is surrounded by shallow trench isolation structures STI, and the gate structures G1 and G2 span the first active area AA1 and the second active area AA2 respectively, so in fact, the gate structures G1 and G2 are not only located on the surfaces of the P-doped region PW and the N-doped region NW, but also located in part of the shallow trench isolation structures. This can be seen more clearly in FIG. 6 below.

It is worth noting that in the present invention, although the active area protruding from the shallow trench isolation structure STI is formed, the process of the present invention is still classified as a planar transistor. More specifically, the process of forming transistors in the first active area AA1 or the second active area AA2 of the present invention is mostly the same as that of planar transistors, and is obviously different from the general process of forming fin transistors. Generally speaking, in the process of fin transistor, in order to form fin structure, it is usually necessary to use multiple masks to perform multiple photolithography and etching steps on the substrate, including forming sacrificial layers and spacers, removing sacrificial layers, performing sidewall pattern transfer (SIT) steps to transfer patterns to stacked material layers and substrates, filling insulating materials and performing back etching. In the step of the present invention, it is not necessary to use a plurality of complicated masks to form the fin structure. The invention is mainly suitable for the processes higher than 22 nm (for example, 22 nm, 28 nm, etc.), that is to say, the structure of the planar transistor is improved in the processes higher than 22 nm. As mentioned above, in the process of higher than 22 nm, most transistors are still planar transistors because there is less requirement on the accuracy of components. In FIG. 1 of the present invention, the positions of the active area (i.e., the first active area AA1 and the second active area AA2) and the shallow trench isolation structure STI are defined, and then the gate structures G1 and G2 are formed on the active area. However, unlike the conventional planar transistor, because a wet etching step P1 (as shown in FIG. 2) is additionally performed in the process, the top surface of the shallow trench isolation structure STI is slightly lowered, and the active area protrudes from the surface of the shallow trench isolation structure STI. However, even if the semiconductor structure of the present invention has a protruding active area, it still belongs to the category of planar transistor, and the protruding active area of the semiconductor structure of the present invention is still obviously different from the general fin structure in structure.

In order to more clearly explain the difference between the structure of the present invention and the fin transistor, FIG. 6 shows a schematic diagram of a semiconductor structure of the present invention and a schematic diagram of a fin transistor respectively. As shown in FIG. 6, the left side shows the structural schematic diagram of the semiconductor structure of the present invention, while the right side shows the structural schematic diagram of a fin transistor. As shown in the left structure, the gate structure G3 spans the active area AA and the shallow trench isolation structure STI to form a transistor. The top surface of the shallow trench isolation structure STI in the present invention is slightly lowered due to etching, so that the active area AA (that is, the aforementioned P-doped region PW or N-doped region NW) protrudes from the top surface of the shallow trench isolation structure STI, but the height difference H1 between the top surface of the shallow trench isolation structure STI and the top surface of the active area AA (please refer to the height H1 in FIG. 2) is only within about 10. On the other hand, in the structure on the right of FIG. 6, the gate structure G4 straddles the fin structure F and the shallow trench isolation structure STI to form a transistor. However, the height H3 of the fin structure is usually about 40 nm, which is usually significantly more than 10 nm, so the height of the protruding active area of the present invention is obviously lower than that of the general fin structure.

On the other hand, since the structure of the present invention is improved based on the structure of the planar transistor, the size of the active area AA is obviously different from that of the fin structure when viewed from the top view. For example, in FIG. 6, the length L1 of the active area AA is about 25 nm and the width W1 is about 250 nm, so the ratio of the length L1 to the width W1 is greater than 0.1 (that is, 25/250). However, the length L2 of the fin structure F will be significantly less than the length L1 of the active area AA. For example, in a general 14 nm process, when the same width W2 is 250 nm, the length L2 of the fin structure F is only about 10 nm, so the ratio of the length L2 to the width W2 of the fin structure F will be significantly less than 0.1. Therefore, the size of the active area AA of the present invention is obviously different from the size of the fin structure F from the perspective of the size in the top view.

In the present invention, the top surface of the shallow trench isolation structure STI of the planar transistor is lowered by the wet etching step P1, and then a gate structure (such as the gate structures G1 and G2 in FIG. 5 or the gate structure G3 in FIG. 6) is formed, so that the gate structure spans the top surface of the active area AA and the sidewalls on both sides of the active area. So that the channel width of the planar transistor is increased, and the performance of the transistor is correspondingly improved. According to the applicant's experimental results, compared with the conventional planar transistor (i.e., the planar transistor without performing additional etching step, so the top surface of the gate structure is aligned with the top surface of the shallow trench isolation STI), the off current (Ioff) of the improved planar transistor of the present invention is increased by about 20%, and the leakage current is decreased by about 12%. When the transistor is applied to SRAM, its driving voltage is also decreased by about 20%. Therefore, on the basis of the existing process of planar transistor, the invention performs additional etching steps for shallow trench isolation structure STI, and can effectively improve the performance of planar transistor without using additional photomask.

Based on the above description and drawings, the present invention provides a method for manufacturing a semiconductor structure, which includes providing a substrate S, on which a shallow trench isolation structure STI is formed and a first active area AA1 is defined, wherein a top surface of the shallow trench isolation structure STI is higher than a top surface of the substrate S of the first active area AA1 (as shown in FIG. 1, before wet etching step P1, The top surface of the shallow trench isolation structure STI is higher than the surface of the substrate S of the first active area AA1), an etching step P1 is performed to remove part of the shallow trench isolation structure STI so that the top surface of the shallow trench isolation structure STI is lower than the top surface of the substrate S of the first active area AA1 (as shown in FIG. 2), and after the etching step, a doping step (as shown in FIG. 4) is performed on the first active area.

In some embodiments of the present invention, after the etching step, a height difference between the top surface of the shallow trench isolation structure STI and the top surface of the first active area AA1 is defined as H1, where H1 is between 2 nm and 10 nm.

In some embodiments of the present invention, after the etching step, a depth of the shallow trench isolation structure STI is defined as D1, wherein the ratio of H1 to D1 is less than 0.05.

In some embodiments of the present invention, from a top view, a length of the first active area AA1 is defined as L1 and a width is defined as W1, wherein the width W1 is less than 250 nm.

In some embodiments of the present invention, the ratio of the length L1 to the width W1 is greater than 0.1.

In some embodiments of the present invention, an oxide layer 14 and a nitride layer 16 are formed on the first active area AA1, and the nitride layer 16 is stacked on the oxide layer 14.

In some embodiments of the present invention, in the etching step, the etching step P1 simultaneously removes a part of the oxide layer 14 so that a width of the oxide layer 14 is smaller than a width of the nitride layer 16 (as shown in FIG. 2, notches 18 and 20 are formed in the oxide layer 14).

In some embodiments of the present invention, after the etching step P1, the oxide layer 14 and the nitride layer 16 are completely removed, and then the doping step P2 is performed.

In some embodiments of the present invention, before the etching step, the top surface of the shallow trench isolation structure STI is aligned with a top surface of the nitride layer 16 in the horizontal direction (as shown in FIG. 1).

In some embodiments of the present invention, the interface of the first active area AA1 and the shallow trench isolation structure STI includes a rounded corner (RC1 as shown in FIG. 4).

In some embodiments of the present invention, after the doping step P2, it further includes forming a first gate structure G1 on the first active area and part of the shallow trench isolation structure, wherein the bottom surface contacted by the first gate structure G1 and the first active area AA1 is defined as a first bottom surface, and the bottom surface contacted by the first gate structure G1 and the shallow trench isolation structure STI is defined as a second bottom surface, wherein the height difference between the first bottom surface and the second bottom surface in a vertical direction is within 10 nm (refer to the 6th.

In some embodiments of the present invention, the etching step includes a wet etching step, and the wet etching step includes a buffered oxide etch (BOE) etching step.

In some embodiments of the present invention, it further includes defining a second active area AA2 located on the substrate S, wherein the shallow trench isolation structure STI is located between the first active area AA1 and the second active area AA2.

In some embodiments of the present invention, the doping step P2 further comprises doping the first active area and the second active area respectively, so as to dope the first active area and the second active area with ions of different conductivity types respectively.

The invention further provides a semiconductor structure, which comprises a substrate S, wherein the substrate S comprises a first active area AA1, and a shallow trench isolation structure STI is located on the substrate S and around the first active area AA1, wherein a top surface of the shallow trench isolation structure STI is lower than a top surface of the substrate of the first active area AA1, and a height difference between the top surface of the shallow trench isolation structure STI and the top surface of the first active area AA1 is defined as H1, where H1 is between 2 nm and 10 nm.

In some embodiments of the present invention, a depth of the shallow trench isolation structure STI is defined as D1, and the ratio of H1 to D1 is less than 0.1.

In some embodiments of the present invention, from a top view, a length of the first active area AA1 is defined as L1 and a width is defined as W1, wherein the width W1 is less than 250 nm, and the ratio of the length L1 to the width W1 is greater than 0.1.

In some embodiments of the present invention, the interface of the first active area AA1 and the shallow trench isolation structure STI includes a rounded corner RC1.

In some embodiments of the present invention, a first gate structure G1 is located on the first active area AA1 and part of the shallow trench isolation structure AA1, wherein the bottom surface contacted by the first gate structure G1 and the first active area AA1 is defined as a first bottom surface, and the bottom surface contacted by the first gate structure G1 and the shallow trench isolation structure is defined as a second bottom surface, wherein the height difference between the first bottom surface and the second bottom surface in a vertical direction is within 10 nanometers.

In some embodiments of the present invention, it further includes a second active area AA2, wherein the shallow trench isolation structure STI is located between the first active area AA1 and the second active area AA2, and the first active area AA1 and the second active area AA2 are respectively doped with ions of different conductivity types.

The invention is characterized in that planar transistors are still the main application components in the intermediate-level semiconductor manufacturing processes such as 22 nm and 28 nm. In the manufacturing process of the planar transistor, the surface of the shallow trench isolation structure is slightly lowered by an additional etching process, so that the original planar active area presents a protruding part similar to the fin structure, thereby improving the performance of the transistor. It is noteworthy that the improved planar transistor of the present invention is different from the conventional fin transistor, and the present invention can form a planar transistor with a protruding active area without multiple additional processes. The planar transistor of the present invention is suitable for intermediate semiconductor processes such as 22 nm and 28 nm, and has the advantages of easy process, simple structure, etc. At the same time, because the active area becomes a protruding structure, the transistor has higher performance.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A manufacturing method of a semiconductor structure, comprising:
providing a substrate, wherein a shallow trench isolation structure and a first active area are formed on the substrate, wherein a top surface of the shallow trench isolation structure is higher than a top surface of the substrate in the first active area;
performing an etching step to remove part of the shallow trench isolation structure so that the top surface of the shallow trench isolation structure is lower than the top surface of the substrate of the first active area; and
performing a doping step on the first active area after the etching step.

2. The method for manufacturing a semiconductor structure according to claim 1, wherein after the etching step, a height difference between the top surface of the shallow trench isolation structure and the top surface of the first active area is defined as H1, where H1 is between 2 nm and 10 nm.

3. The method for manufacturing a semiconductor structure according to claim 2, wherein after the etching step, a depth of the shallow trench isolation structure is defined as D1, wherein the ratio of H1 to D1 is less than 0.05.

4. The method for manufacturing a semiconductor structure according to claim 1, wherein, from a top view, a length of the first active area is defined as L1 and a width is defined as W1, wherein the width W1 is less than 250 nm.

5. The method for manufacturing a semiconductor structure according to claim 4, wherein the ratio of the length L1 to the width W1 is greater than 0.1.

6. The method for manufacturing a semiconductor structure according to claim 1, further comprising forming an oxide layer and a nitride layer on the first active area, wherein the nitride layer is stacked on the oxide layer.

7. The method for manufacturing a semiconductor structure according to claim 6, wherein a part of the oxide layer is removed during the etching step, so that a width of the oxide layer is smaller than a width of the nitride layer.

8. The method for manufacturing a semiconductor structure according to claim 6, wherein after the etching step, the oxide layer and the nitride layer are completely removed, and then the doping step is then performed.

9. The method for manufacturing a semiconductor structure according to claim 6, wherein before the etching step, the top surface of the shallow trench isolation structure is aligned with a top surface of the nitride layer in the horizontal direction.

10. The method for manufacturing a semiconductor structure according to claim 1, wherein the interface of the first active area and the shallow trench isolation structure comprises a rounded corner.

11. The method for manufacturing a semiconductor structure according to claim 1, wherein after the doping step, further comprising forming a first gate structure on the first active area and part of the shallow trench isolation structure, wherein a bottom surface of the first gate structure contacting the first active area is defined as a first bottom surface, and a bottom surface of the first gate structure contacting the shallow trench isolation structure is defined as a second bottom surface, wherein the height difference between the first bottom surface and the second bottom surface in a vertical direction is within 10 nanometers.

12. The method for manufacturing a semiconductor structure according to claim 1, wherein the etching step comprises a wet etching step, and the wet etching step comprises a buffered oxide etch (BOE) etching step.

13. The method for manufacturing a semiconductor structure according to claim 1, further comprising forming a second active area in the substrate, wherein the shallow trench isolation structure is located between the first active area and the second active area.

14. The method for manufacturing a semiconductor structure according to claim 13, wherein the doping step further comprises doping the first active area and the second active area respectively, so as to dope the first active area and the second active area with ions of different conductivity types.

15. A semiconductor structure, comprising:
a substrate including a first active area;
a shallow trench isolation structure located on the substrate and around the first active area, wherein a top surface of the shallow trench isolation structure is lower than a top surface of the substrate of the first active area, and a height difference between the top surface of the shallow trench isolation structure and the top surface of the first active area is defined as H1, where H1 is between 2 nm and 10 nm.

16. The semiconductor structure according to claim 15, wherein a depth of the shallow trench isolation structure is defined as D1, and the ratio of H1 to D1 is less than 0.1.

17. The semiconductor structure according to claim 15, wherein when viewed from a top view, a length of the first active area is defined as L1 and a width is defined as W1, wherein the width W1 is less than 250 nm, and the ratio of the length L1 to the width W1 is greater than 0.1.

18. The semiconductor structure according to claim 15, wherein the interface of the first active area and the shallow trench isolation structure comprises a rounded corner.

19. The semiconductor structure according to claim 15, further comprising a first gate structure on the first active area and part of the shallow trench isolation structure, wherein a bottom surface of the first gate structure contacting the first active area is defined as a first bottom surface, and a bottom surface of the first gate structure contacting the shallow trench isolation structure is defined as a second bottom surface, wherein the height difference between the first bottom surface and the second bottom surface in a vertical direction is within 10 nanometers.

20. The semiconductor structure according to claim 15, further comprising a second active area, wherein the shallow trench isolation structure is located between the first active area and the second active area, and the first active area and the second active area are respectively doped with ions of different conductivity types.
